(19) United States
(12) Patent Application Publication
(10) Pub. No.: US 2012/0196229 A1
(43) Pub. Date: Aug. 2, 2012

(54) EMBEDDING DATA INTO SOLID AREAS, TEXT OR LINE WORK

(76) Inventor: Kurt M. Sanger, Rochester, NY (US)

(21) Appl. No.: 13/017,260

(22) Filed: Jan. 31, 2011

(51) Int. Cl. G03F 7/20

(52) U.S. Cl. 430/306

(57) ABSTRACT

A method of encoding data in printed solid image features on a receiver includes providing a relief printing member; modifying at least one surface of the relief printing member within a boundary of a solid image feature; and printing the encoded data in at least one solid image feature on the receiver.

### CROSS REFERENCE TO RELATED APPLICATIONS

Reference is made to commonly-assigned copending U.S. patent application Ser. No. ______ (Attorney Docket No. K000038US01NAB), filed herewith, entitled EMBEDDING DATA INTO SOLID AREAS, TEXT OR LINEWORK, by Sanger et al.; the disclosure of which is incorporated herein.

### FIELD OF THE INVENTION

This invention pertains in general to flexographic printing and in particular to encoding data in solid printing areas.

### BACKGROUND OF THE INVENTION

There are many advantages to encoding data into printed works. One may wish to encode copyright information, additional information about a product, a remote internet address or link, or encrypted data to indicate authenticity or make it more difficult to copy. One common data encoding method is to embed a watermark within the image. U.S. Pat. No. 7,174,031 (Rhoads et al.) list many methods of encoding data in images. In addition it discusses many additional uses for encoded data.

There are few methods available for encoding data into printed materials that do not contain a grey scale or continuous tone image in which to hide a watermark. U.S. Pat. No. 7,555,139 (Rhoads et al.) encodes data by changing the width of lines and text characters. U.S. Pat. No. 6,449,377 (Rhoads) discloses varying line to line spacing to encode data. U.S. Pat. No. 5,761,686 (Bloomberg) adds encoded features which are of the same relative size and spacing as the text in a print to camouflage the encoded data.

There is a need to be able to encode data in prints that contain solid features, line work, line art, and text. Many labels do not contain images that are conducive to having a watermark added to them. Changing the line width or line spacing of features within the label may be objectionable to the originator of the graphics. Changing the character width of a text font may be objectionable as many fonts are chosen as part of corporate branding, product branding, or may be a component of a trademark. Addition of a barcode or 2D binary pattern requires additional space on the print and may result in additional labels being added to the package. Even if the artwork contains an image suitable for adding a watermark, there may still be a desire for additional information or additional security features.

Many labels and packaging materials are printed using flexography. Flexography is a printing method that uses a relief plate. Flexographic relief plates may be made from rubber or a photopolymer. Traditional rubber plate precursors may be molded, carved, or ablated with a laser to form the relief. Photopolymer plate precursors are exposed with ultra-violet light through a mask to harden the photopolymer. Then the unexposed polymer is washed out, the plate is dried, then an additional ultra-violet exposure is used to detack or cure any remaining uncured photopolymer. The exposed areas form the relief used to print the image.

The relief is typically 500 um to 1000 um measured from the top of the plate to the floor or non-imaging portion of the plate. For a photopolymer plate the floor is exposed from the back side and may be varied by changing the back side ultra-violet exposure. Both rubber and photopolymer plates are typically mounted to a polyester support. Plates are mounted to printing cylinders or sleeves using a double back compressible tape. Engraved rubber-coated cylinders or sleeves are also used. Unless otherwise specified in the following description, the term plate refers to any form of relief printing member.

In a flexographic printing press, ink is coated onto an Anilox roll and then transferred to the flexographic relief plate. The plate is then impressed against a receiver backed by an impression roller. Receivers may be uncoated paper, coated paper, polymers, glass, ceramics, wood, corrugated board, hard board, or metals. The printed density is dependent upon the Anilox cell volume, the ink, the pressure between the plate and the Anilox roller, the pressure between the plate and the receiver, and the receiver.

To print grey scale images, relief features comprising size-modulated halftone dots or spatial frequency-modulated dots are used. Artistic methods such as line drawings may also be used. The grey scale or tone scale is calibrated by printing test patches with no compensation. The density of each patch is measured and an effective dot area is computed based on the measured density. Then a compensation curve is created to compute the dot area required to obtain a desired density curve. Flexographic printing has difficulty imaging extremely small dots. Dots between 0% and 5% by area, less than 20 um in diameter, may image extremely dark or not image at all. Typically press operators limit the smallest dot size printed to a minimum of 4-10%, 20-30 um diameter, to avoid these quality issues. The dot gain when printing a 20% dot on plate may result in a density that corresponds approximately to 50% dot area coverage. Flexography has a typical 25-35% dot gain at a 20% input level. The printed density keeps increasing until the 80-90% dot level, at which point density then decreases to the solid density at 100%. This behavior results in a calibration curve that starts at 0%, jumps to a minimum output dot of 4-6%, then a region of image highlights between 4-10%, a region of midtones between 10-30%, a region of shadow details between 40%-85%, and finally solid features are imaged at 100%. The compression of the highlights makes them difficult to control and increases the quantization on the print. The tone scale on press will also depend upon how the plate relief is made and the impression between the plate and the receiver.

Color images are printed using flexography by employing well known color separation techniques wherein each color has its own grey scale image. Calibrating each color and simultaneously controlling every color on press is a challenge. Newer presses with feedback on impression and servo-driven cylinders, along with digitally created plates, have enabled color flexographic printing that rivals offset lithography.

The local relief within a grey scale image will be much lower than the relief between the top of the plate and the floor. For a photopolymer plate a 50% tint will have a local relief depth between dots of 100-200 um. A single 20 um×20 um hole corresponding to a 98.6% halftone at 150 lines per inch will have a depth of 10-30 um.

Recent advances as taught in U.S. Publication No. 2010/0143841 (Stolt et al.) discuss modifying the plate surface by applying a pattern to substantially all image feature sizes of the halftone image data to reduce the transparency of image areas of a mask by a constant amount. The resultant mask can be affixed to a plate precursor to form an intimate contact with, and a gaseous barrier to, the plate precursor. The plate precursor can then be exposed to curing radiation and the mask removed. After processing, the precursor forms a relief plate carrying a relief image that resolves the pattern in the surface of relief features. The print densities of solid features are substantially maintained or increased when the pattern is applied to solid relief features. Among the advantages of using this method are increased dynamic range and more uniform density.

### SUMMARY OF THE INVENTION

Briefly, according to one aspect of the present invention, data is embedded into solids, line work, line art, or text, by modifying the surface of a relief printing plate. Embedded data may be human readable or machine readable. Embedded data may be encrypted. Embedded data may be hidden or camouflaged. Embedded data may be difficult to copy.

The invention and its objects and advantages will become more apparent in the detailed description of the preferred embodiment presented below.

### BRIEF DESCRIPTION OF THE DRAWINGS

FIG. 1a is a prior art magnified image of a solid feature printed using flexographic press.

FIG. 1b is a prior art magnified image of a character printed using a flexographic press.

FIG. 2a is a prior art magnified image of a solid feature printed on a flexographic press using a relief plate with surface treatment.

FIG. 2b is a prior art magnified image of a character printed on a flexographic press using a relief plate with surface treatment.

FIG. 3 is a magnified image of a print made with an embodiment of the present invention.

FIG. 4 is a schematic illustrating an embodiment of the present invention.

FIG. 5 is a schematic illustrating an embodiment of the present invention.

FIG. 6a depicts a prior art bitmap of a solid image feature.

FIG. 6b depicts a prior art modified bitmap of a solid image feature modified with a surface feature.

FIG. 6c depicts a prior art expanded view of the modified surface feature.

FIG. 6d depicts a bitmap embodiment of the present invention with a second surface pattern.

FIG. 6e depicts a bitmap embodiment of the present invention with a third surface pattern.

FIG. 6f depicts a bitmap embodiment of the present invention with a fourth surface pattern.

FIG. 7a depicts a modified bitmap of a solid image feature with a surface pattern and embedded data.

FIG. 7b shows an expanded view of a surface pattern.

FIG. 7c is an expanded view of a modified bitmap containing human readable embedded data.

FIG. 7d is an expanded view of a modified bitmap containing human readable embedded data.

FIG. 7e is an expanded view of a modified bitmap containing machine readable embedded data.

FIG. 7f is an expanded view of a modified bitmap containing machine readable embedded data.

FIG. 8a depicts a modified bitmap of a solid text object containing embedded data using the present invention.

FIG. 8b is an expanded view of a modified bitmap of a solid text object containing embedded data using the present invention.

FIG. 8c is an expanded view of a modified bitmap of a solid text object containing embedded data using the present invention.

FIG. 9 is a plot of a horizontal scan line for a solid feature printed using a relief member with and without surface features.

FIG. 10 is a plot of an average horizontal scan line for a solid feature printed using a relief member with and without surface features.

FIG. 11 is a plot of a horizontal scan line in the middle of a solid character ‘m’ printed using a relief member with and without surface features.

FIG. 12 is a plot of an average horizontal scan line in the middle of a solid character ‘m’ printed using a relief member with and without surface features.

### DETAILED DESCRIPTION OF THE INVENTION

The present invention is directed in particular to elements forming part of, or in cooperation more directly with the apparatus in accordance with the present invention. It is to be understood that elements not specifically shown or described may take various forms well known to those skilled in the art.

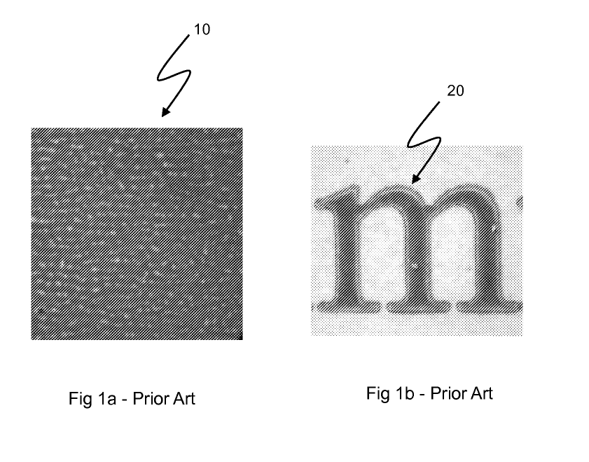

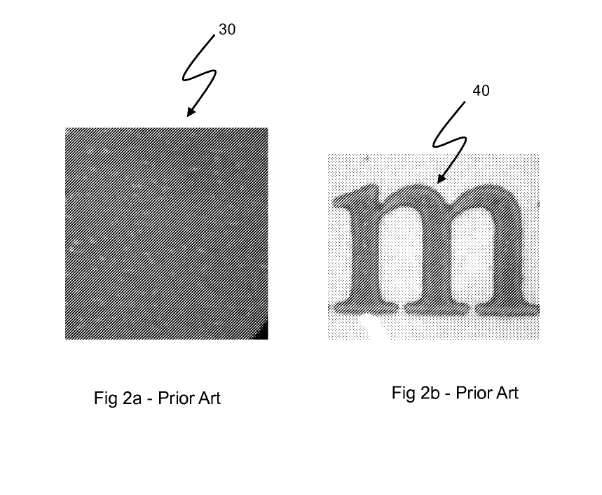

Referring now to FIG. 1a item 10 is a magnified print of a solvent-based cyan ink imaged onto a white polymer receiver using a flexographic press with a Kodak Flexcel NX Plate with no surface treatment. The cyan density measured 1.33 Status T Red Density Absolute. FIG. 1b item 20 is a magnified print of the letter “m” imaged on the same plate under the same conditions. In FIG. 2a item 30 is a magnified print of the same cyan ink imaged onto the same white polymer receiver using the same flexographic press with a Kodak Flexcel NX Plate with the surface treatment defined in U.S. Publication No. 2010/0143841. The solid density measured 1.52 Status T Red Density Absolute. In FIG. 2b item 40 is a magnified print of the letter “m” imaged the same as FIG. 2a. The solid area density and solid area density uniformity are improved in FIGS. 2a and 2b over FIG. 1a and FIG. 1b by applying the methods disclosed in U.S. Publication No. 2010/0143841.

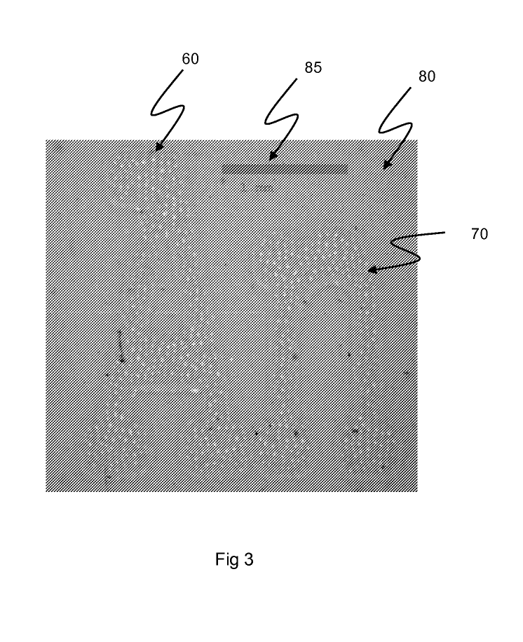

FIG. 3 depicts one embodiment of the present invention. FIG. 3 is a magnified view of a solid image area 80 printed with a cyan ink which has the surface treatment defined by U.S. Publication No. 2010/0143841 applied everywhere except for the areas defined by the letters “A” 60 and “n” 70. The line segment 85 is scaled to indicate a 1 mm distance in the original solid image area 80. FIG. 3 shows that changing the surface roughness of solid image features of a flexographic relief printing plate may be used to encode data in the solid image features. In this case the data is encoded as the characters “A” and “n”. These characters are human readable, however one skilled in the art will recognize that one could have modified the surface roughness in the shape of lines, squares, 2D patterns, barcodes, or other machine- and human-readable forms.

Solid image features are those regions of an image where there are no halftone dots and substantially 100% ink coverage of at least one color ink. In printing with a relief member the solid image features are printed by transferring ink from the raised surface of the relief member to a receiver. One skilled in the art will recognize that shadow halftone dots making a hole in the relief layer on the order of 100 um² to 900 um² area may plug or fill in with ink. In addition pressure between the relief member and a receiver may cause the ink to fill in the area of the shadow halftone dot effectively printing a continuous layer of ink on the receiver. For flexographic printing the relief member is a flexographic plate and the shadow dots typically between 80% to 100% and more typically between 90% and 100% may substantially create a continuous layer of ink on the receiver. One skilled in the art will recognize that the present invention may be applied and will work in these areas of shadow halftone dots. Similarly isolated dots on the order of 100 um² to 900 um² may also plug and substantially create a continuous layer of ink on the receiver. Image shadow areas of frequency modulated screens with shadow areas typically from 80% to 100% and more typically from 90% to 100% may substantially create a uniform layer of ink on the receiver. The present invention may be applied to image shadow areas between 80% to 100% dot to embed data within the shadow image area.

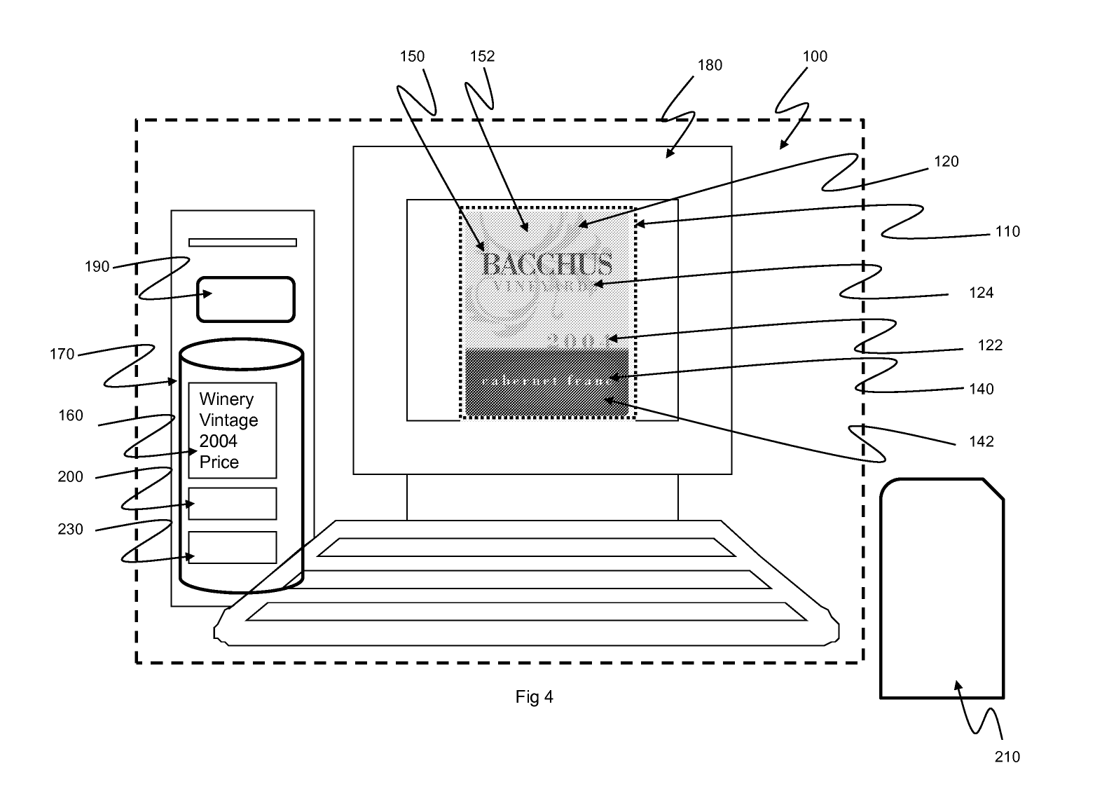

Referring to FIG. 4, workstation 100 contains customer artwork 110 comprising numerous objects including; solid area 142, reverse text 140, background 152, line work 120, line work text 122, line work text 124, and text 150.

A first method of printing the customer artwork 110 uses a single color ink to print solid image features consisting of solid area 142 and text 150. Then background 152 is screened at a first % tint while line work 120, text 124, and text 122 are screened at a second % tint darker than the first % tint. This results in screened text characters for text 122 and text 124, plus screened lines on line work 120. Screened text and screened lines may show jagged edges and may be objectionable to the customer. The invention is used to modify the solid image features comprising solid areas 142 and solid text 150 to contain embedded data.

A second method of printing customer artwork 110 uses two inks having different color. Solid image features comprising solid area 142 and text 150 are imaged as solid image features with a first color ink. Solid image features comprising image line work 120, text 122, and text 124, are printed with a second color ink also as solid objects. Background 152 is screened using either the first or second color inks or a combination of both. The invention is used to modify solid image features comprising solid area 142, solid text 150, solid line work 120, solid text 122, and solid text 124 to contain embedded data.

A third embodiment of the invention uses the second method with the addition of printing the background 152 with a third color ink as a solid image feature. The invention is used to embed additional data in the solid background 152 using the third color ink.

One skilled in the art will recognize that first, second, and third colored inks may all be of the same hue with different amounts of intensity. In addition all three inks may be different levels of black or grey. For purposes of this invention black, white and grey inks are considered to be colors. The customer artwork may be printed onto receivers comprising uncoated paper, coated paper, colored paper, metal, polymer, glass, ceramic, hard board, wood, corrugated board, label stock, or other receiver.

The data to be encoded 160 may be stored on storage device 170 on workstation 100. Storage devices may be hard disks, random access memory, floppy media, compact disk, network storage devices, solid state disk, or other data storage devices. The customer artwork 110 may also be stored on storage device 170 or displayed on monitor 180. Workstation 100 also contains an image processor 190 which converts customer artwork 110 into bitmap files 200 for each color to be printed at the writing resolution of the film writer 210. In addition the image processor encodes the data to be encoded 160 to fit into the solid image features comprising at least one of solid area 142, text 150, line work 120, text 122, text 124, or background 152, creating a modified bitmap 230. Modified bitmap 230 contains the original bitmap 200 with the encoded data. The image processor creates a modified bitmap 230 for each of the colors to be printed in the customer artwork 110.

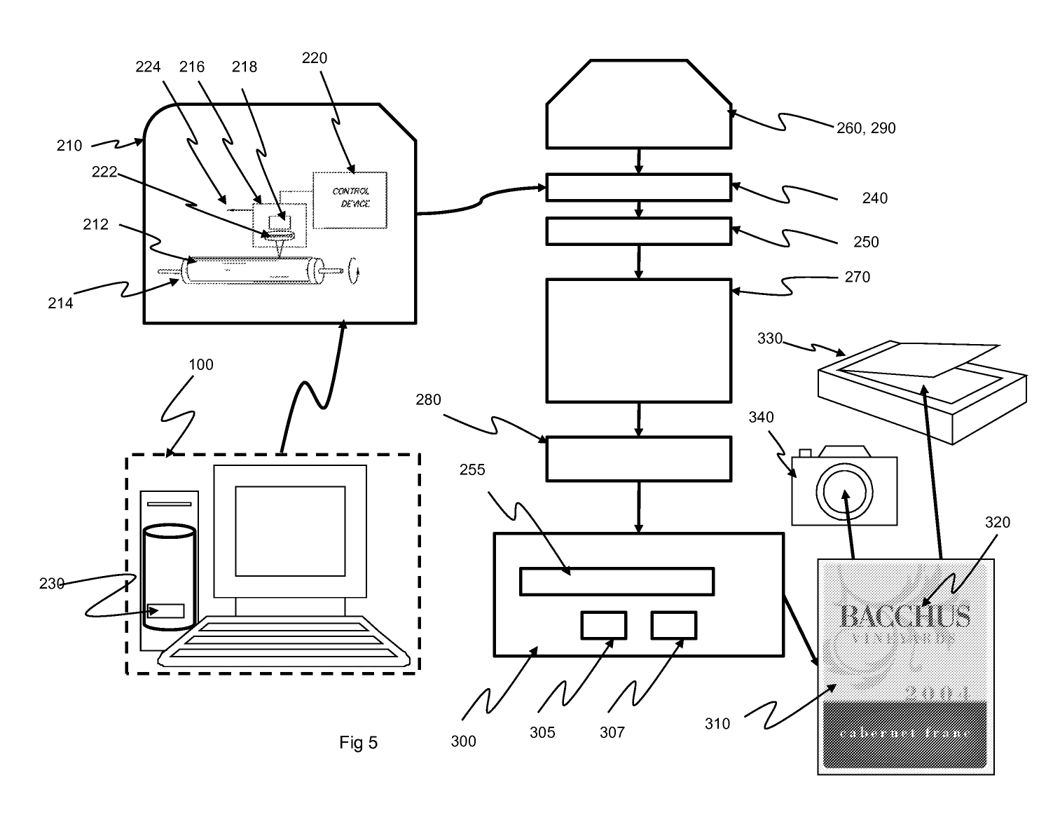

Referring to FIG. 5, the workstation 100 then sends the modified bitmap 230 to the control device 220 of a film writer 210 which is used to create a mask 240. The control device 220 controls a laser 218 using the modified bitmap 230 which is imaged through a lens 222 onto a film 212 to create mask 240. The film 212 is mounted on a rotating drum 214. The laser 218 and lens 222 compose a print head 216 which translates in a translation direction 224 in combination with the spinning drum 214 in order write the whole film 212 to create the written mask 240.

The written mask 240 is affixed to an unexposed relief printing member precursor 250. The precursor 250 is then exposed to actinic radiation 260 and the mask 240 is removed. The exposed precursor 250 is then processed in a processor 270, baked in an oven 280, then post cured using additional actinic radiation 290 forming a relief printing member 255.

One skilled in the art will recognize various well-known alternate means of modifying the relief printing member within the scope of the present invention. Optionally, the film may be integral with the relief member precursor prior to the writing of the mask. Alternatively, the mask may be affixed by lamination, or by vacuum holder or may be loose. Alternatively, the precursor may be exposed by projection through the mask and a lens system. The mask may be imaged by ablating a film with a laser or a thermal head. A mask may be generated on a relief printing member precursor or carrier substrate by thermal dye transfer or by inkjet.

Alternatively the film writer 210 and mask 240 may be substituted with a direct writing system in which the modified bitmap is directly written to a photosensitive relief printing precursor with actinic radiation or the modified bitmap is used to control a direct laser engraver that creates relief on a relief printing member by ablation.

Flexographic relief printing member contains a relief image for one of the colors in customer artwork 110 along with embedded data 160 which is encoded in the solid surface of the relief printing member 255. The relief printing member 255 is mounted into a flexographic printing press 300. Ink 305 is applied to the relief printing member and then transferred to a receiver 307 to produce the customer artwork 110 onto printed stock resulting in a printed piece 310. The printed piece contains at least one solid image feature with embedded data 320.

A camera 340 or a page scanner 330 may be used to capture an image of the printed piece 310 with embedded data 320. A second image processor, not shown, may be used to process the scanned image, decode the embedded data, and present it to a customer, user, manufacturer, supplier, or publisher.

Relief printing members may be flexographic printing plates, flexographic printing sleeves with an integral relief plate, flexographic printing sleeves with a removable relief plate, flexographic printing cylinders with an integral relief plate, flexographic printing cylinders with a removable relief plate, rubber stamps, or rubber molds or other relief printing members used to transfer ink to a receiver.

Relief printing members may be created by engraving with a laser, wherein the image processor creates a bitmap of the customer artwork at the writing resolution of the laser engraver, the embedded data is embedded into the solid image features within the bitmap, and the laser engraver uses the bitmap to engrave the relief printing member. The laser engraver may be a direct write plate writer.

Relief printing members may be created by ablating an integral laser ablation mask wherein the image processor creates a bitmap of the customer artwork at the writing resolution of the laser ablation mask writer and the embedded data is embedded into the solid image features within the bitmap, and the laser ablation mask writer uses the bitmap to ablate the mask of the relief printing member. Subsequently, the relief printing precursor comprising the imagewise ablated integral mask is exposed to curing radiation through the mask and processed to remove the mask and uncured material.

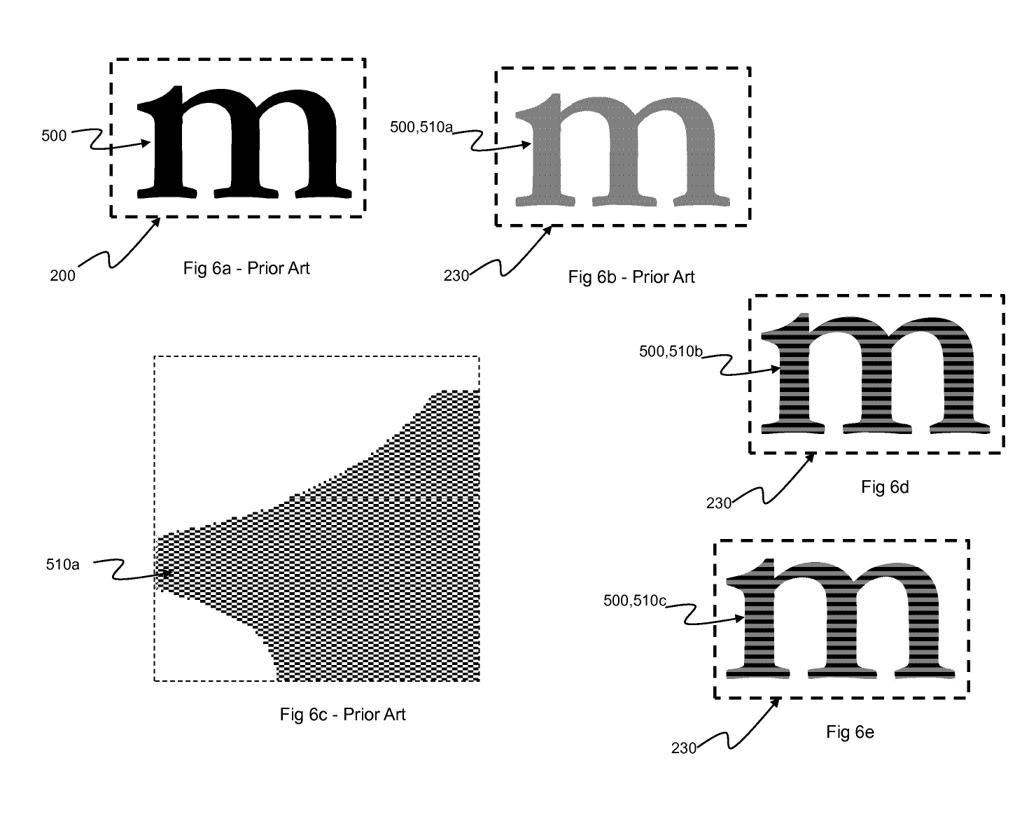

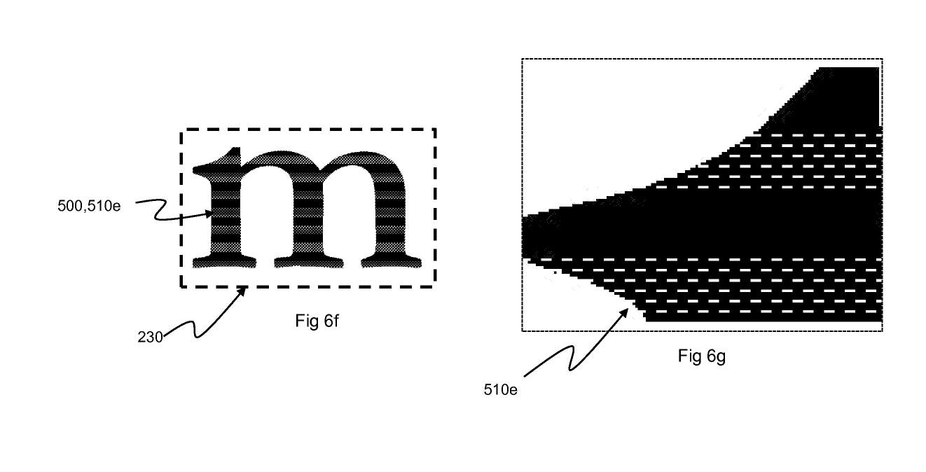

FIG. 6a depicts a bitmap 200 of a 12-point Arial font letter “m” 500 at 4800 dpi pixel by 4800 dpi line resolution. FIG. 6b depicts a modified bitmap 230 of the letter “m” 500 at 4800 dpi pixels by 4800 dpi line resolution which is modified with surface feature 510a. FIG. 6c is an expanded view of the modified bitmap 230 with surface feature 510a also at 4800 dpi pixels by 4800 dpi lines.

FIG. 6d depicts a modified bitmap 230 of a 12-point Arial font letter “m” 500 at 4800 dpi pixels by 4800 dpi line resolution which is modified with a second surface feature 510b. Second surface feature 510b consists of rows of unmodified solid areas and rows of modified solid areas. FIG. 6e depicts a modified bitmap 230 of a 12-point Arial font letter “m” 500 at 4800 dpi pixels by 4800 dpi line resolution which is modified with a third surface feature 510c. Third surface feature 510c consists of rows of modified solid areas and rows of unmodified solid areas. Third surface feature 510c is out of phase with second surface feature 510b. One skilled in the art will recognize that one may encode data by modifying the phase of the modified surface features, the pattern of the modified surface features, or the geometry of the modified surface features.

FIG. 6f depicts a modified bitmap 230 of a 12-point Arial font letter “m” 500 at 4800 dpi pixels by 4800 dpi line resolution which is modified with a fourth surface feature 510e. FIG. 6g is an expanded view of the fourth surface feature 510e. One skilled in the art will recognize that surface feature modifications of different sizes and orientations may be used to create features in the surface that will print differently, thus enabling encoding data in solid surfaces.

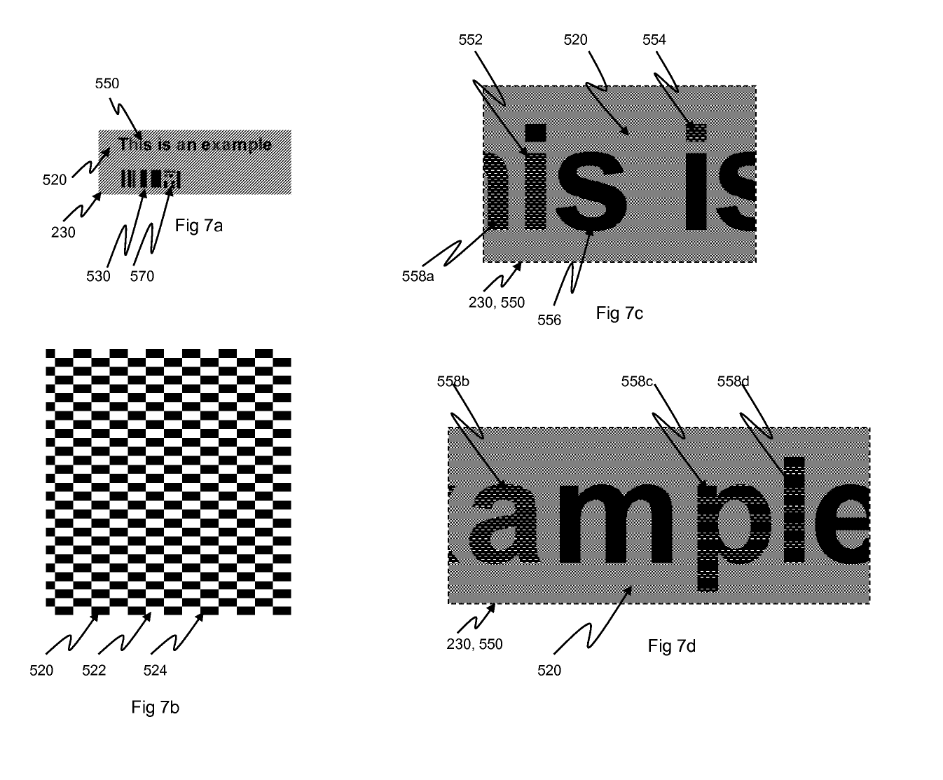

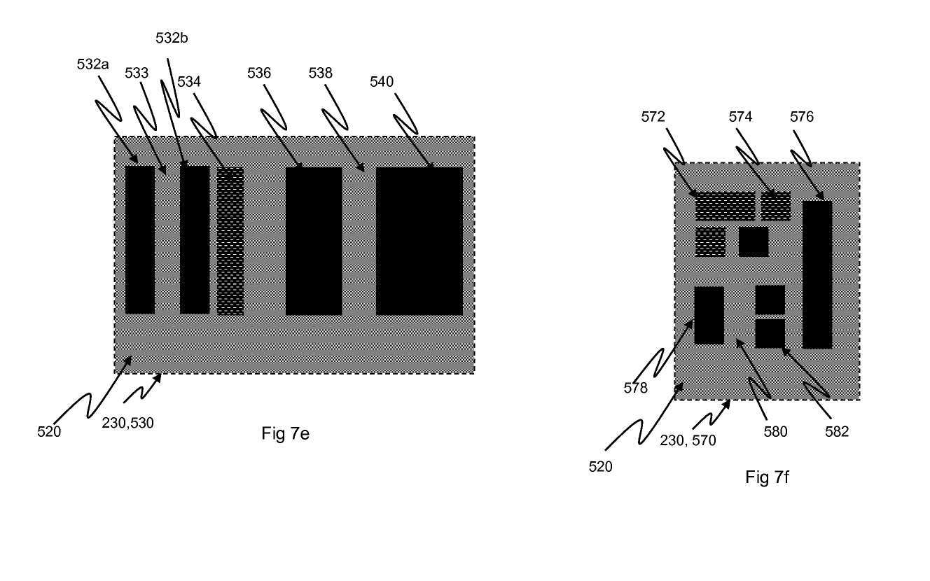

FIG. 7a depicts a modified bitmap 230 of a solid image feature with a surface pattern 520, embedded human readable data 550, embedded one-dimensional barcode data 530, and embedded two-dimensional data 570. FIG. 7b is an expanded view of the surface pattern 520. Each on pixel 522 and off pixel 524 is a feature 1/2400 inches wide by 1/4800 inches tall.

FIGS. 7c and 7d are expanded views of modified bitmap 230 of a solid object with a surface pattern 520 and embedded human-readable data 550. Human-readable data is encoded in the patterned solid surface pattern 520 using one or more of a second surface feature in a lower portion of a character 552, a second surface feature in an upper portion of a character 554, a second surface feature in a whole character 558b, a third surface consisting of an unmodified solid surface feature in a character 556, a fourth surface feature with a first phase in a character 558c, and a fourth surface feature with a second phase in a character 558d. One skilled in the art will recognize that human-readable data 550 encoded with one or more surface features may also include machine-readable data.

FIG. 7e is an expanded view of modified bitmap 230 of a solid area with a surface pattern 520 and embedded machine-readable data in the form of a one-dimensional bar code 530. Bar code 530 may comprise lines of different widths 532, 536, 540, and spaces 538. Spaces may also be different widths. Lines may be modulated with unmodified solid surface features as shown in lines 532, 536, and 540, or with a third surface feature as shown in line 534. Note that the solid area has a first surface pattern 520. The lines without surface patterns 532a, 532b, 536, and 540 on the relief member have a second surface pattern. Therefore the line 534 has a third surface pattern. It is understood that the use of a set of two or more patterns to encode date may include as one of the patterns the null or unmodified solid feature.

FIG. 7f is an expanded view of a modified bitmap 230 of a solid image feature with a surface pattern 520 and embedded machine-readable data in the form of a two-dimensional code 570. Two-dimensional code 570 may include one or more image features of different sizes as shown by rectangular solid areas 578, 582, and 576 having a second surface including an unpatterned relief surface; image features in a second orientation such as rectangles 578 and 572; image features with a third surface pattern such as rectangles 572 and 574; and a space 580. Note that the image features with the unmodified solid areas 578, 582, and 576, therefore are solid areas with a second surface pattern.

The encoded data may be detected by scanning the print with a scanner, a camera, a camera phone, a microscope, a camera with a macro lens, a microscope with a camera, by eye, or by visually with magnification. The encoded data may be detected by moving the print past a line scanning device. The encoded data may be detected by capturing an image of the print with an area detection device. Once an image of the print has been captured, the solid areas may be evaluated to determine if there is encoded data by looking at the density variability or noise of solid areas. Characters or image features may be recognized and evaluated to determine if the density distribution follows or matches a known profile. Solid areas may also be evaluated to determine if there is a presence of a halftone or frequency-modulated screen which would indicate that a printed piece has been copied and reproduced using a halftone or frequency-modulated screen. Edges of solid areas may also be evaluated to determine if the solid has been reproduced using a grey-scale method.

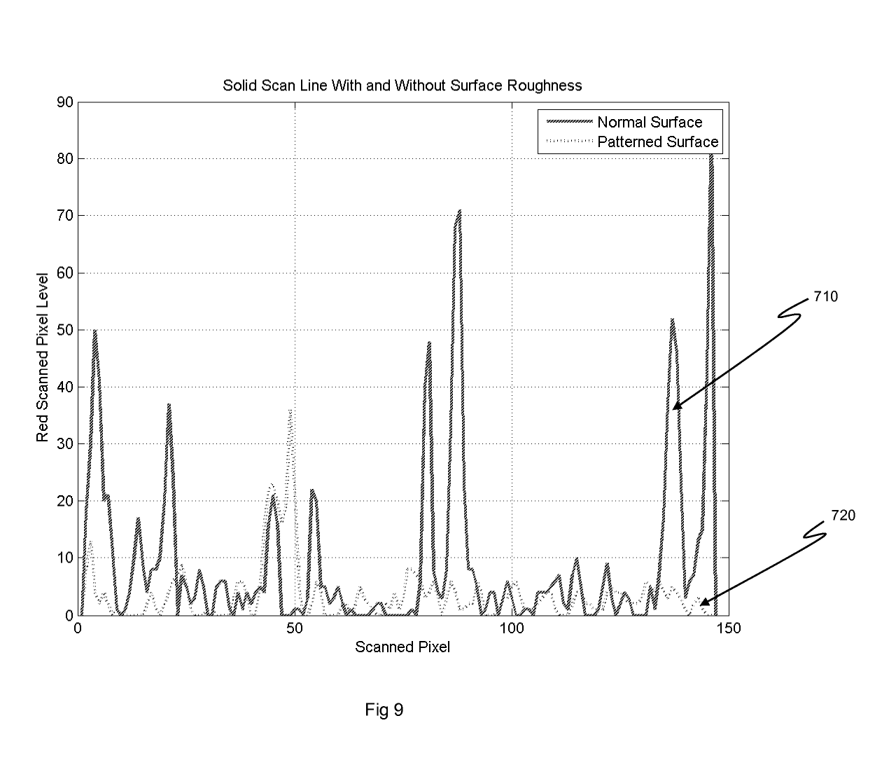

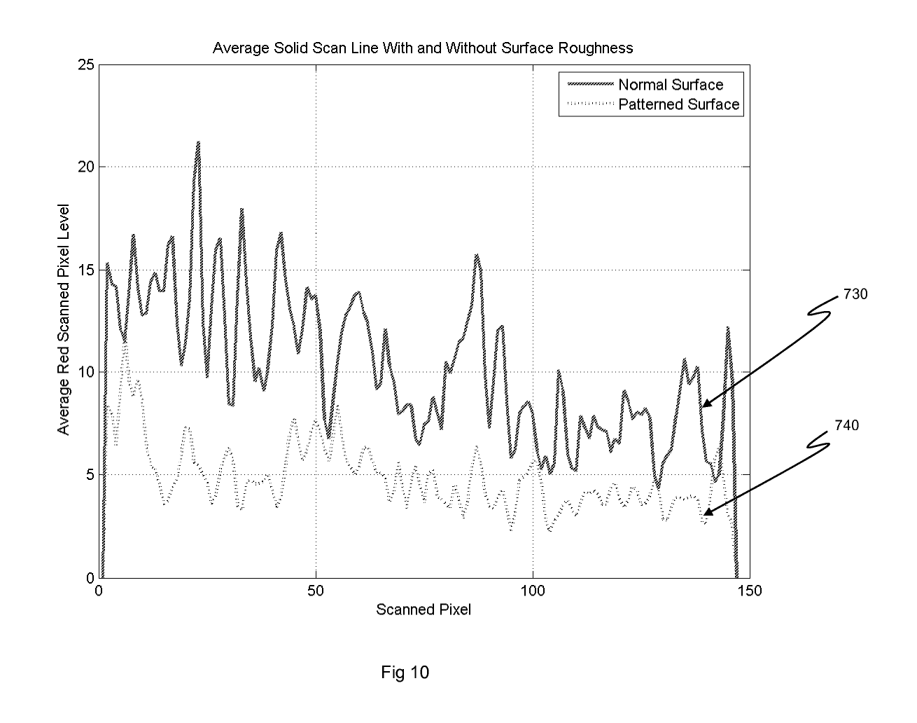

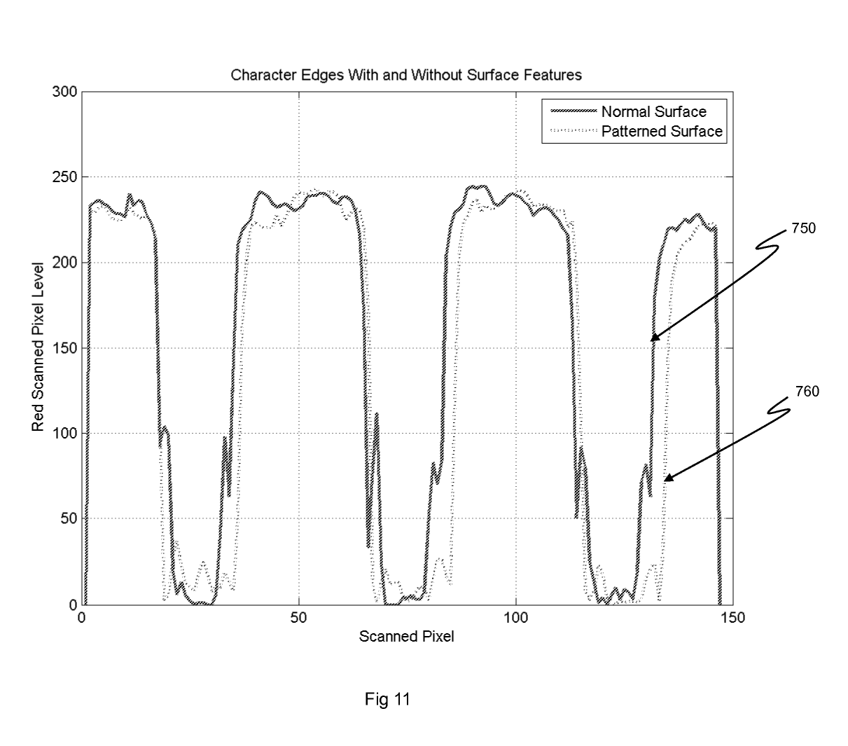

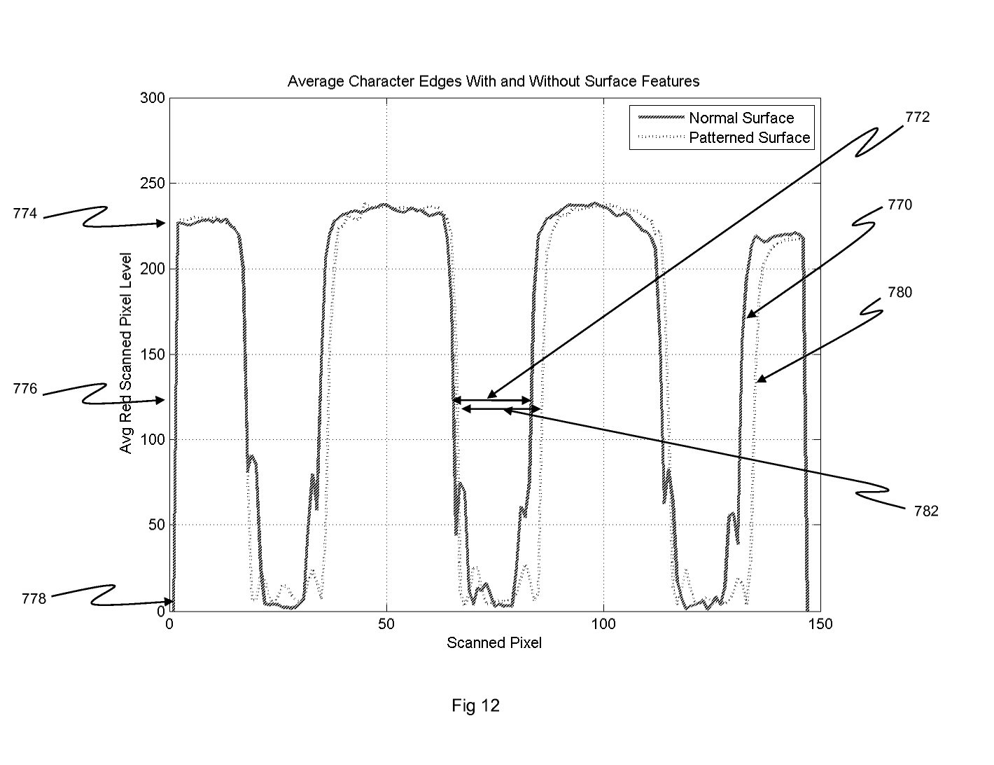

Many differences in the solid image features caused by roughening or patterning the surface of the relief printing member may be used to encode embedded data. One embodiment encodes data using characters with and without patterning the surface of the individual character image features of the relief printing member. FIGS. 1a and 1b depict examples of solid image features consisting of a solid 10 and a character 20 with a first solid surface feature consisting of an unpatterned solid surface. FIGS. 2a and 2b depict examples of solid image features consisting of a solid 30 and a character 40 with a second solid surface feature created by patterning or roughening the surface of the relief printing member. An example of how to detect the encoding from scanned images containing embedded data in solid image features using this invention is as follows. FIG. 9 is a plot of the RGB (red, green, blue) red pixel value for each pixel in a single horizontal line of the solid without surface patterns 710 from FIG. 1a 10, and the solid with surface patterns 720 from FIG. 2a 30. Note that the peak-to-peak values of the solid area without surface patterns 710 are much greater than the peak-to-peak values of the solid area with surface features 720. FIG. 10 is a plot of the average red pixel value for sixty horizontal lines by pixel for the solid area without surface features 730 and the solid area with surface features 740. The average red pixel value is lower for the solid area with surface features 740 indicating that the average density of the solid area with surface features 740 is darker than the average density of the solid area with surface features 730. FIG. 11 is a plot of single red pixel values for an RGB scan of the ‘m’ character without surface features 750 as shown in FIG. 1b 20, and single red pixel values of an RGB scan of the ‘m’ character with surface features 760 as shown in FIG. 2b 40. Note that the ‘m’ character is a positive character meaning that the ink prints the character and not the surround. Also note that darker pixels have lower RGB values such that the letter ‘m’ is a red code value below 125 and the paper is near red code value 235. The full width half max (FWHM) width of the legs of the letter ‘m’ with and without surface features are for all practical purposes the same. The pronounced halo effect of the non-patterned surface causes the density to oscillate as the scan traverses from paper to ink and ink to paper. This oscillation is detectable to indicate whether the surface is patterned. FIG. 12 is a plot of an average of forty horizontal lines centered about the middle of the letter ‘m’. The average line for the letter ‘m’ without surface features 770 has the same full width half maximum width 772 as the FWHM width 782 of the average line for the letter ‘m’ with surface features 780. The maximum density is approximately at the minimum red code value 778. The minimum density or paper density is at the maximum red code value 774. The half maximum density 776 is near red code value one hundred and twenty-five. The rising and falling edge of the density trace is steeper for the letter ‘m’ with surface patterning 780 indicating a sharper character. The average red code value for levels lower than the half maximum density 776, is lower for the surface patterned letter ‘m’ 780 indicating that it has a higher average density.

A sharpness difference, a density difference, or a density variability or uniformity difference may be used to distinguish coded data in a character or solid area printed with a relief plate. A sharpness difference, a density difference, or a density variability or uniformity difference may be used to distinguish a printed solid image feature printed with a first solid surface pattern from a second printed solid image feature printed with a second solid surface pattern. A sharpness difference, a density difference, or a density variability or uniformity difference may be used to distinguish a printed solid image feature printed with a first solid surface roughness from a second printed solid image feature printed with a second solid surface roughness.

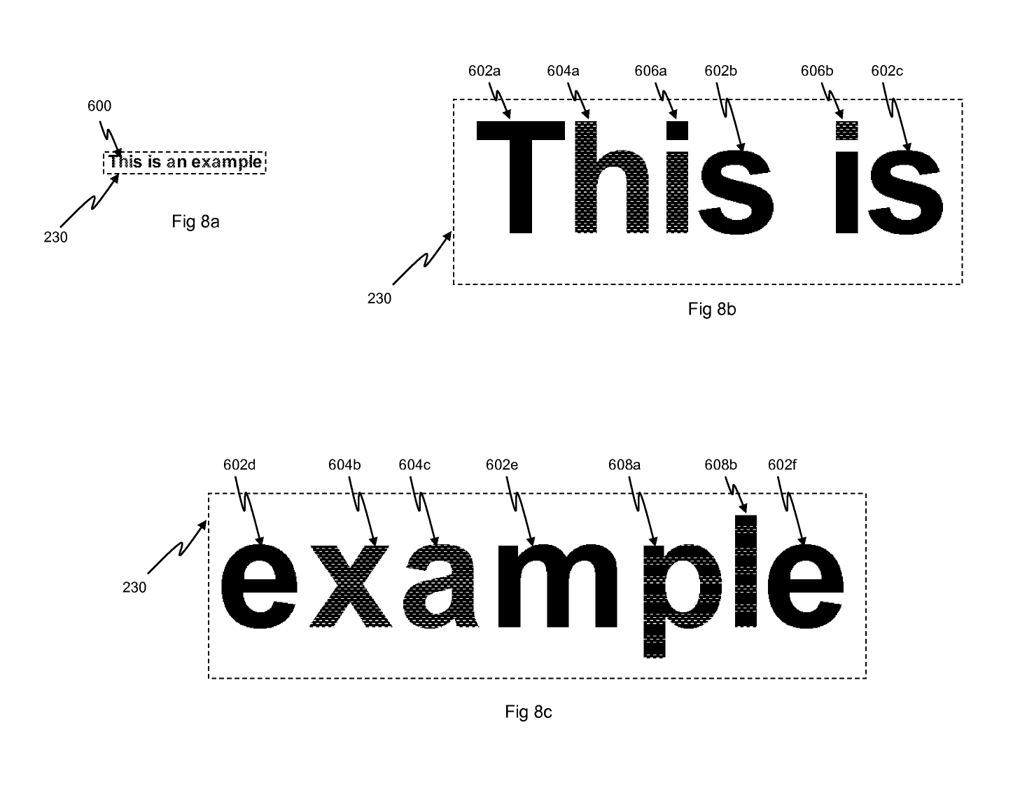

Scanned characters or scanned solid image features may be classified to have been printed with solid surface features as in FIG. 1b item 20 or printed with solid surface features as in FIG. 2b item 40. FIG. 8a depicts a modified bitmap 230 containing a solid text feature 600 that has been modified on a character-by-character basis to encode data. FIG. 8b shows a portion of the modified bitmap 230 with unmodified surface solid characters 602a, 602b, and 602c; a character with a modified surface 604a using a first pattern; a character with a modified surface using a first pattern on the lower portion of the character 606a; and a character with a modified surface using a first pattern on the upper portion of the character 606b. FIG. 8c shows a portion of the modified bitmap 230 with unmodified surface solid characters 602d, 602e, and 602f; characters with a modified surface using a first pattern 604b and 604c; a character with a modified surface using a second pattern with a first phase 608a; and a character with a modified surface using a second pattern with a second phase 608b.

In FIG. 8c each character comprising a solid surface 602d, 602e, 602f, is scored with a value of zero. Characters coded with a first surface pattern 604b, 604c, are scored with a one. Characters coded with a second surface pattern with a first phase 608a are scored as a two, and characters coded with a second surface pattern with a second phase 608b are given the score of three. This gives the base four number 0110230 which may also be decoded as binary 00 00 01 01 00 10 11 00, or decimal 1324. One skilled at the art will recognize that many additional coding methods may be used to encrypt data into solid image features, line work, line art and text using relief printing members with solid image features by modifying the surface of the relief printing member with various patterns within the boundaries of the solid image features.

In a preferred embodiment of the invention the modifications to the surface of the relief printing member roughen the surface by creating pits that are 2 to 30 um deep and less than 30 um wide by 30 um long. In a more preferred embodiment of the invention the pits are 3-10 um deep and 5 um wide by 10 um long. The pits may be round, square, or an easily created shape. The surface of the relief member may be roughened by creating an opaque feature in a mask which is used during the exposure of a photo-sensitive relief member precursor. The surface of the relief member may be roughened by etching the surface. The surface of the relief member may be roughened by laser ablating the surface. The surface of the relief member may be roughed by chemically processing the surface. The surface of the relief member may be roughened by machining the surface.

FIG. 7e is an expanded view of a solid image feature comprising a line art feature modified bitmap 230 in the shape of a rectangle with a first surface pattern 520 in the majority of the feature. A one-dimensional encoding comprising of 532a, 532b, 533, 534, 536, 538, and 540, is within the boundary of the feature. Narrow lines with a second surface pattern 532a, and 532b, made without surface patterns are each given the score of one. A narrow space 533 is scored as a zero. A narrow line made with a third surface pattern 534 is scored as a value of two. FIG. 7e is decoded as a narrow line with a second surface feature, a narrow space, a narrow line with a second surface feature, a narrow line with a third surface feature, two narrow spaces, a wide line equal to two narrow lines with a second surface feature, one narrow space, and wider line equal to three narrow lines with a second surface feature providing a base three number of 101200110111 or decimal 210289.

One skilled in the art will recognize that the solid image feature may be printed with a first surface feature that may or may not be patterned. Then the embedded data may be printed with a minimum of a second surface feature that may be the opposite of the surround.

It is an advantage of the present invention that we may encode data in solids with more than one bit of resolution per encoded mark. This significantly increases the amount of data that may be stored in solid areas.

One skilled in the art will recognize that we may encode data other than numeric data such as ASCII characters, Kanji characters, unicodes, or mixed data sets.

The invention has been described in detail with particular reference to certain preferred embodiments thereof, but it will be understood that variations and modifications can be effected within the scope of the invention.

### PARTS LIST

10 solid image feature without surface pattern
20 character without surface pattern
30 solid image feature with surface pattern
40 character with surface pattern
60 letter “A” without surface pattern
70 letter “n” without surface pattern
80 solid image feature with surface pattern
85 line segment
100 workstation
110 customer artwork
120 line work
122 text
124 text
140 reverse text
142 solid area
150 text
152 background
160 encoded data
170 storage device
180 monitor
190 image processor
200 bitmap
210 film writer
212 film
214 drum
216 print head
218 laser
220 control device
222 lens
224 translation direction
230 modified bitmap
240 mask
250 plate precursor
255 relief printing member
260 actinic radiation
270 plate processor
280 oven
290 curing radiation
300 flexographic printing press
305 ink
307 receiver
310 printed piece
320 embedded data
330 scanner
340 camera
500 letter “m”
510a surface feature
510b second surface feature
510c third surface feature
510e fourth surface feature
520 surface pattern
522 on pixel
524 off pixel
530 one-dimensional barcode data
532a narrow line with a second surface pattern
532b narrow line with a second surface pattern
533 narrow space
534 line with a third surface pattern
536 line with unmodified surface pattern
538 space
540 line with unmodified surface pattern
550 human readable data
552 character with second surface pattern in lower portion
554 character with second surface pattern in upper portion
556 character with unmodified surface
558a character
558b character with second surface pattern
558c character with fourth surface pattern at a first phase
558d character with fourth surface pattern at a second phase
570 two-dimensional data
572 rectangle at a second orientation and a third surface pattern
574 rectangle with a third surface pattern
576 rectangle with unmodified second surface
578 rectangle with unmodified second surface in a second orientation
580 space
582 rectangle with unmodified second surface
600 solid text feature
602a unmodified surface solid character
602b unmodified surface solid character
602c unmodified surface solid character
602d unmodified surface solid character
602e unmodified surface solid character
602f unmodified surface solid character
604a modified surface using first pattern
604b modified surface using first pattern
604c modified surface using first pattern
606a character with modified surface on lower portion using a first pattern
606b character with modified surface on upper portion using a first pattern
608a modified surface using second pattern with first phase
608b modified surface using second pattern with second phase
710 horizontal line scan of solid without surface pattern
720 horizontal line scan of solid with surface pattern
730 average horizontal line scan of solid without surface feature
740 average horizontal line scan of solid with surface feature
750 horizontal line scan of character ‘m” without surface feature
760 horizontal line scan of character ‘m” with surface feature
770 average horizontal scan of character ‘m’ without surface feature
772 full width half maximum (FWHM) width
774 maximum red code value
776 half maximum density
778 minimum red code value
780 average horizontal scan of character ‘m’ with surface feature
782 full width half maximum (FWHM) width

1. A method of encoding data in printed solid image features on a receiver comprising:
providing a relief printing member;
modifying at least one surface of the relief printing member within a boundary of a solid image feature; and
printing the encoded data in at least one solid image feature on the receiver.

2. The method as in claim 1 wherein the solid image feature is a line work feature, a text character, or a solid area.

3. The method as in claim 1 comprising:
creating a modified bitmap comprising the encoded data within the boundary of a solid image feature; and
ablating the surface of the relief printing member with a laser to modify the surface according to the modified bitmap.

4. The method of claim 1 wherein the relief printing member is an ultraviolet curable printing member comprising:
creating a modified bitmap comprising the encoded data within the boundary of the solid image feature;
creating a mask with the modified bitmap;
exposing the relief printing member through the mask; and
processing the relief printing member.

5. The method of claim 1 wherein the relief printing member comprises a flexographic printing member.

6. The method of claim 5 wherein the flexographic printing member comprises a flexographic plate, a flexographic sleeve, or a flexographic cylinder.
